(19) United States
(12) Patent Application Publication
(10) Pub. No.: US 2024/0146214 A1
(43) Pub. Date: May 2, 2024

(54) ELECTROSTATIC CHUCK UNIT AND DEPOSITING APPARATUS INCLUDING THE SAME

(71) Applicant: Samsung Display Co., LTD., Yongin-si (KR)

(72) Inventors: MINCHUL SONG, Yongin-si (KR); JUNHYEUK KO, Yongin-si (KR); MINGOO KANG, Yongin-si (KR); EUIGYU KIM, Yongin-si (KR); Sukha Ryu, Yongin-si (KR); YOUNGSUN CHO, Yongin-si (KR)

(21) Appl. No.: 18/446,274

(22) Filed: Aug. 8, 2023

(30) Foreign Application Priority Data
Oct. 31, 2022 (KR) 10-2022-0142208

(51) Int. Cl. H02N 13/00; C23C 14/50

(52) U.S. Cl. CPC H02N 13/00; C23C 14/50

(57) ABSTRACT

An electrostatic chuck unit includes: a first plate having a first surface and a second surface facing each other and a first hole extending from the first surface to the second surface; a second plate on the first surface of the first plate and having a groove corresponding to the first hole; a coupling bolt inserted into the first hole and the groove; and a height adjusting member spaced apart from the coupling bolt in a plan view.

### CROSS-REFERENCE TO RELATED APPLICATION

This application claims priority to and the benefit of Korean Patent Application No. 10-2022-0142208, filed in the Korean Intellectual Property Office (KIPO) on Oct. 31, 2022, the entire content of which is incorporated herein by reference.

### BACKGROUND

### 1. Field

Aspects of embodiments of the present disclosure relate to an electrostatic chuck unit and depositing apparatus including the same.

### 2. Description of the Related Art

A display device is a device that is configured to provide visual information to a user by displaying an image. The display device may be used in small products, such as mobile phones, and large products, such as televisions.

A manufacturing process of the display device may include a deposition process of forming a thin film on a surface of a target substrate.

### SUMMARY

Embodiments of the present disclosure provide an electrostatic chuck unit that reduces or prevents defects during a deposition process.

Embodiments of the present disclosure also provide a deposition apparatus that reduces or prevents defects during a deposition process.

A display device, according to an embodiment of the present disclosure, includes a first plate having a first surface and a second surface facing each other and a first hole extending from the first surface to the second surface, a second plate on the first surface of the first plate and having a groove corresponding to the first hole, a coupling bolt inserted into the first hole and the groove, a height adjusting member spaced apart from the coupling bolt in a plan view.

In an embodiment, the first plate may have a second hole extending from the first surface to the second surface and spaced apart from the groove in the plan view, and the height adjusting member may include a height adjusting bolt inserted into the second hole.

In an embodiment, a length of the height adjusting bolt exposed through the first plate may be shorter than a length of the coupling bolt exposed through the first plate.

In an embodiment, the height adjusting member may further include a washer on the height adjusting bolt.

In an embodiment, the height adjusting member may be a spacer between the first plate and the second plate.

In an embodiment, the spacer may include at least one selected from a metal material, an inorganic insulating material, and ceramic.

In an embodiment, the spacer may include a same material as the first plate and the second plate.

In an embodiment, the height adjusting member may contact the second plate.

In an embodiment, the second plate may be spaced apart from the first plate by the height adjusting member.

In an embodiment, the first plate and the second plate may be coupled to each other by the coupling bolt.

In an embodiment, the first plate may have a protrusion protruding from the first surface toward the second plate.

In an embodiment, the first plate and the second plate may include at least one selected from a metal material, an inorganic insulating material, and ceramic.

In an embodiment, the first plate and the second plate may include the same material as each other.

In an embodiment, the electrostatic chuck unit may further include a base frame supporting the first plate and the second plate.

In an embodiment, the base frame may have an opening, and the first plate and the second plate may be in the opening.

A deposition apparatus, according to an embodiment of the present disclosure, includes a chamber, a mask unit in the chamber and including a mask sheet and a mask frame supporting the mask sheet, and an electrostatic chuck unit in the chamber and configured to receive a target substrate thereon. The electrostatic chuck unit includes a first plate having a first surface and a second surface facing each other and a first hole extending from the first surface to the second surface, a second plate on the first surface of the first plate and having a groove corresponding to the first hole, a coupling bolt inserted into the first hole and the groove, and a height adjusting member spaced apart from the coupling bolt in a plan view.

In an embodiment, the first plate may have a second hole extending from the first surface to the second surface and spaced apart from the groove in the plan view, and the height adjusting member may include a height adjusting bolt inserted into the second hole.

In an embodiment, the height adjusting member may be a spacer between the first plate and the second plate.

In an embodiment, the second plate may be spaced apart from the first plate by the height adjusting member.

In an embodiment, the electrostatic chuck unit and the mask unit may be arranged such that the target substrate and the mask sheet face each other along a direction parallel to the ground.

The electrostatic chuck unit, according to embodiments of the present disclosure, may have a multi-stage structure including a first plate and a second plate disposed on the first plate. Also, the electrostatic chuck unit may include the height adjusting member that partially (or minutely) adjusts the height (or flatness) of the second plate. For example, the distance between the second plate and the first plate may be partially adjusted at each position corresponding to the height adjusting member by using (or changing, etc.) the height adjusting member. Accordingly, a flatness of the target substrate seated on the second plate can be easily adjusted and corrected. Accordingly, the distance between the target substrate and the mask sheet facing the target substrate can be easily adjusted and corrected through the height adjusting member. Accordingly, defects occurring in the deposition process may be reduced or prevented.

It is to be understood that both the foregoing general description and the following detailed description provides examples and explanations and are intended to describe aspects and features of the present disclosure.

### BRIEF DESCRIPTION OF THE DRAWINGS

Aspects and features of the present disclosure will be more clearly understood from the following detailed description, taken in conjunction with the accompanying drawings, in which:

FIG. 1 is a cross-sectional view illustrating a deposition apparatus according to an embodiment.

FIG. 2 is a plan view illustrating the electrostatic chuck unit shown in FIG. 1,

FIG. 3 is a cross-sectional view illustrating the electrostatic chuck unit shown in FIG. 1.

FIG. 4 is a flowchart illustrating steps for adjusting the height of a second plate included in the electrostatic chuck unit shown in FIG. 3.

FIGS. 5 to 10 are cross-sectional views illustrating steps of a method of adjusting the height of the second plate included in the electrostatic chuck unit shown in FIG. 3.

FIG. 11 is a cross-sectional view illustrating an electrostatic chuck unit according to another embodiment.

FIG. 12 is a cross-sectional view illustrating an electrostatic chuck unit according to another embodiment.

FIG. 13 is a cross-sectional view illustrating a pixel formed in a deposition process using the deposition apparatus shown in FIG. 1.

### DETAILED DESCRIPTION

The present disclosure will be described more fully hereinafter with reference to the accompanying drawings, in which various embodiments are shown. The present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

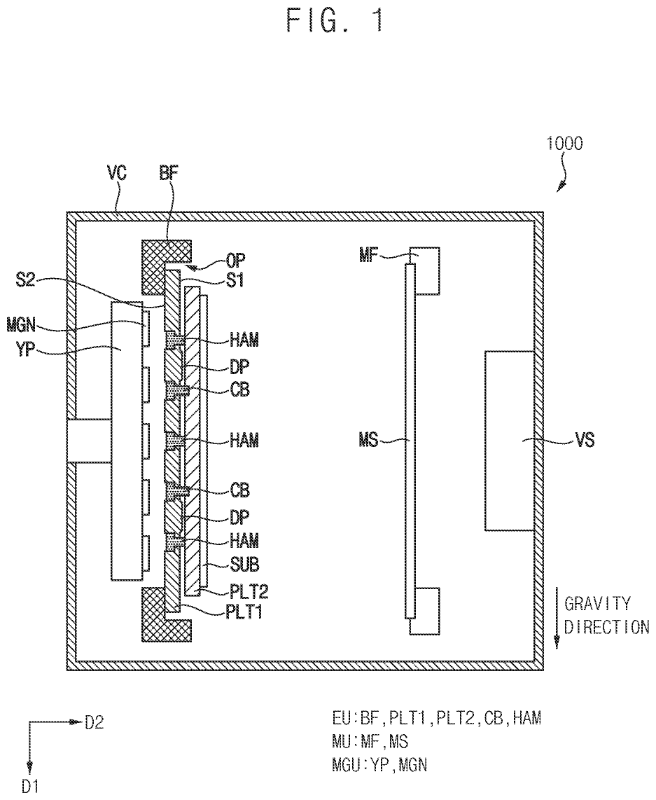

FIG. 1 is a cross-sectional view illustrating a deposition apparatus according to an embodiment.

Referring to FIG. 1, a deposition apparatus 1000, according to an embodiment, may be used in a deposition process for manufacturing a display device. For example, the deposition apparatus 1000 may be an apparatus for depositing an organic film or an electrode film on a target substrate SUB. The deposition apparatus 1000 may include a chamber VC, an electrostatic chuck unit EU, a mask unit MU, a deposition source VS, and a magnet unit MGU.

The chamber VC may provide a space for performing the deposition process. For example, the deposition process may be performed inside the chamber VC. In an embodiment, the chamber VC may have a rectangular parallelepiped shape. For example, the chamber VC may have an upper surface, a lower surface, and side surfaces. The lower surface may face the upper surface in a first direction D1. The side surfaces may be vertically connected to (e.g., may extend between) the upper surface and the lower surface, respectively. However, the present disclosure is not necessarily limited thereto, and the chamber VC may have various suitable shapes.

In an embodiment, the inside of the chamber VC may be in a vacuum state. For example, the chamber VC may be connected to a vacuum pump. In an embodiment, the chamber VC may include a conductive material.

The electrostatic chuck unit EU may be disposed in the chamber VC. The electrostatic chuck unit EU may seat (e.g., may hold or accommodate) the target substrate SUB as it is carried into the chamber VC. For example, the electrostatic chuck unit EU may chuck or de-chuck (e.g., may hold or release) the target substrate SUB by electrostatic force.

In an embodiment, the electrostatic chuck unit EU may have a length extending in the first direction D1. In an embodiment, the first direction D1 may be a gravitational direction. For example, the first direction D1 may be perpendicular to the ground and parallel to gravity. The electrostatic chuck unit EU may be disposed (e.g., may be disposed to face) perpendicular to the ground. Accordingly, when the target substrate SUB is seated on the electrostatic chuck unit EU, a front surface of the target substrate SUB may be vertically disposed (or aligned) with respect to the ground.

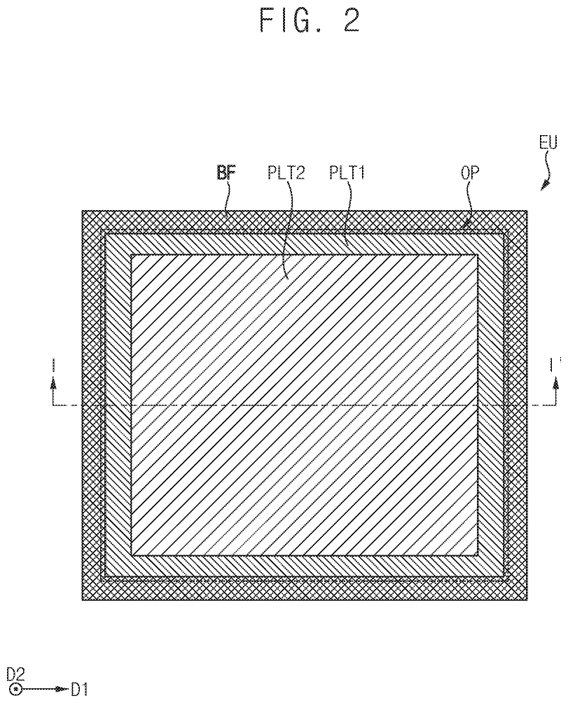

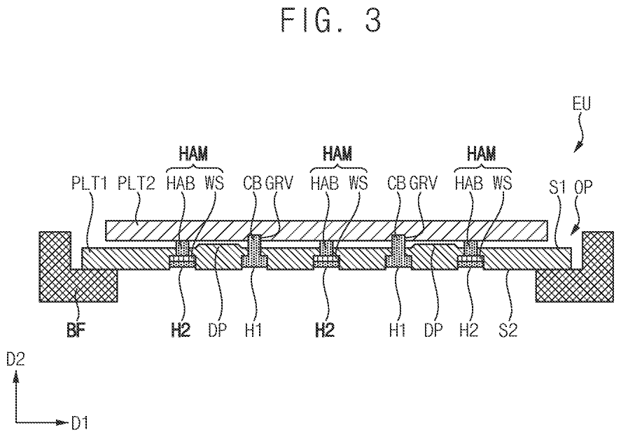

A detailed structure of the electrostatic chuck unit EU will be described later with further reference to FIGS. 2 and 3.

The mask unit MU may be spaced apart from the electrostatic chuck unit EU in the chamber VC in a second direction D2 perpendicular to the first direction D1. The second direction D2 may be a direction parallel to the ground. For example, the mask unit MU may be disposed to face the electrostatic chuck unit EU. The mask unit MU may have a length extending in the first direction D1. As described above, the first direction D1 may be perpendicular to the ground. The mask unit MU may be disposed perpendicular to the ground.

The mask unit MU may include a mask frame MF and a mask sheet MS.

The mask frame MF may support the mask sheet MS. In an embodiment, the mask frame MF may include a metal material. Examples of metal materials that can be used as the mask frame MF may include stainless steel, Invar alloy (also known as FeNi₃₆), nickel, cobalt, or the like. These metal materials may be used alone or in combination with each other.

The mask sheet MS may be disposed on the mask frame MF. A portion of the mask sheet MS may overlap a portion of the mask frame MF. For example, the mask sheet MS may be seated on a partial area of the mask frame MF.

A front surface of the mask sheet MS may be disposed perpendicular to the ground. For example, the target substrate SUB, seated on the electrostatic chuck unit EU, and the mask sheet MS, disposed on the mask frame MF, may face each other in the second direction D2. The mask sheet MS may have a plurality of openings (or holes). Accordingly, a deposition material may be provided to the target substrate SUB through the plurality of openings in the mask sheet MS.

The deposition source VS may be spaced apart from the mask unit MU in the second direction D2 in the chamber VC. The deposition source VS may store a deposition material, heat the deposition material, and spray the (vaporized) deposition material onto the target substrate SUB to deposit the deposition material on the target substrate SUB.

In an embodiment, the deposition source VS may include at least one nozzle. The deposition source VS may spray the deposition material toward the mask unit MU through the nozzle. For example, the deposition source VS may spray the deposition material in a direction opposite to the second direction D2 through the nozzle. The deposition source VS may spray the deposition material in a direction parallel to the ground. As described above, the deposition material sprayed from the nozzle may pass through the plurality of openings in the mask sheet MS and may be deposited on the target substrate SUB.

In FIG. 1, the deposition source VS is illustrated as being fixed in the chamber VC, but the present disclosure is not necessarily limited thereto. For example, in another embodiment, a separate moving unit for moving the deposition source VS may be disposed in the chamber VC.

The magnet unit MGU may be spaced apart from the electrostatic chuck unit EU in a direction opposite to the second direction D2 in the chamber VC. The magnet unit MGU may include a yoke plate YP and a magnet MGN. The magnet MGN may be a permanent magnet or an electromagnet.

The magnet unit MGU may provide magnetic force to the electrostatic chuck unit EU and the mask unit MU. The target substrate SUB and the mask sheet MS may be brought into close (or closer) contact with each other due to the magnetic force provided by the magnet unit MGU. Accordingly, sagging at a center portion of each of the target substrate SUB and the mask sheet MS may be reduced or prevented. In other embodiments, however, the magnet unit MGU may be omitted.

In FIG. 1, the deposition apparatus 1000 is shown as having a vertical deposition structure, but the present disclosure is not necessarily limited thereto. For example, in another embodiment, the deposition apparatus 1000 may have a horizontal deposition structure in which the electrostatic chuck unit EU and the mask unit MU have a length extending in the second direction D2, and in the chamber VC, the magnet unit MGU, the electrostatic chuck unit EU, the mask unit MU, and the deposition source VS may be spaced apart from each other along the first direction D1. In such an embodiment, the deposition source VS may spray the deposition material in a direction opposite to the first direction D1.

FIG. 2 is a plan view illustrating the electrostatic chuck unit shown in FIG. 1, and FIG. 3 is a cross-sectional view illustrating the electrostatic chuck unit shown in FIG. 1. FIG. 3 may be a cross-sectional view taken along the line I-I′ of FIG. 2. Hereinafter, the electrostatic chuck unit EU included in the deposition apparatus 1000 will be described in more detail with reference to FIGS. 2 and 3.

Referring to FIGS. 1 to 3, the electrostatic chuck unit EU may include a base frame BF, a first plate PLT1, a second plate PLT2, a coupling bolt CB, and a height adjusting member HAM.

The base frame BF may support the first plate PLT1 and the second plate PLT2. In an embodiment, the base frame BF may have a ring shape. In some embodiments, the base frame BF may have a rectangular annular shape having two long sides and two short sides. However, the present disclosure is not necessarily limited thereto, and the shape of the base frame BF may vary according to the shapes of the first plate PLT1 and the second plate PLT2.

An opening OP may be defined in the base frame BF. For example, the opening OP may be defined in a central area of the base frame BF. The first plate PLT1 and the second plate PLT2 may be disposed in the opening OP. In an embodiment, the opening OP may have a ring shape. In some embodiments, the opening OP may have a rectangular annular shape having two long sides and two short sides. However, the present disclosure is not necessarily limited thereto, and the shape of the opening OP may vary according to the shape of the base frame BF.

In an embodiment, the base frame BF may include a metal material. Examples of metal materials that can be used as the base frame BF may include stainless steel, Invar alloy, nickel, cobalt, or the like. These metal materials may be used alone or in combination with each other.

The first plate PLT1 may be disposed on the base frame BF. For example, the first plate PLT1 may be disposed in the opening OP of the base frame BF. A portion of the first plate PLT1 may overlap a portion of the base frame BF. For example, a partial area of the base frame BF may be an area where the first plate PLT1 is substantially seated. In an embodiment, the first plate PLT1 may be fixed to the base frame BF by a separate fastener. In an embodiment, the first plate PLT1 may be fixed to the base frame BF through a bonding process, such as a welding process.

The first plate PLT1 may have a first surface S1 and a second surface S2 that face each other. For example, the first surface S1 may be an upper surface of the first plate PLT1, and the second surface S2 may be a lower surface of the first plate PLT1.

The first plate PLT1 may have a first hole (or first opening) H1 penetrating (or extending) from the first surface S1 to the second surface S2. The first hole H1 may correspond to a groove GRV in the second plate PLT2, to be described later. For example, the first hole H1 may overlap (or may be aligned with) the groove GRV in a plan view. In the embodiment shown in FIG. 3, the first plate PLT1 has two first holes H1, but the present disclosure is not necessarily limited thereto. In another embodiment, the first plate PLT1 may have one first hole H1 or three or more first holes H1.

The first plate PLT1 may have a second hole (or second opening) H2 penetrating (or extending) from the first surface S1 to the second surface S2. The second hole H2 may be spaced apart from the groove GRV in the second plate PLT2 in a plan view. In the embodiment shown in FIG. 3, the first plate PLT1 has three second holes H2, but the present disclosure is not necessarily limited thereto. In other embodiments, the first plate PLT1 may have one second hole H2 or three or more second holes H2.

The second plate PLT2 may be disposed on the first plate PLT1. For example, the second plate PLT2 may be disposed on (or over) the first surface S1 of the first plate PLT1. The second plate PLT2 has the groove GRV defined therein. The groove GRV may pass through (e.g., may extend a depth into) a portion of the second plate PLT2 from the lower surface of the second plate PLT2. The groove GRV may correspond to (e.g., may be aligned with) the first hole H1 in the first plate PLT1. For example, the groove GRV may overlap the first hole H1 in the first plate PLT1 in a plan view. The groove GRV may be spaced apart from the second hole H2 in the first plate PLT2 in a plan view.

In the embodiment shown in FIG. 3, the second plate PLT2 has two grooves GRV, but the present disclosure is not necessarily limited thereto. In other embodiments, the second plate PLT2 may have one groove GRV or three or more grooves GRV defined therein.

Each of the first plate PLT1 and the second plate PLT2 may be formed of a metal material, an inorganic insulating material, ceramic, or the like. Examples of metal materials that can be used for each of the first plate PLT1 and the second plate PLT2 may include aluminum (Al), platinum (Pt), palladium (Pd), silver (Ag), magnesium (Mg), gold (Au), Nickel (Ni), Neodymium (Nd), Iridium (Ir), Chromium (Cr), Lithium (Li), Calcium (Ca), Molybdenum (Mo), Titanium (Ti), Tungsten (W), Copper (Cu), or the like. These materials may be used alone or in combination with each other. In addition, examples of inorganic insulating materials that can be used for each of the first plate PLT1 and the second plate PLT2 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. These materials may be used alone or in combination with each other. In an embodiment, the first plate PLT1 and the second plate PLT2 may include the same material.

Electrodes may be disposed on the second plate PLT2. When voltage is applied to the electrodes, the target substrate SUB may be chucked or de-chucked by (e.g., adhered to or released from) the electrostatic chuck unit EU. For example, as shown in FIG. 1, the target substrate SUB may be seated on the second plate PLT2.

In an embodiment, the electrodes may have the same polarity. In such an embodiment, the target substrate SUB and the electrodes may be charged in a monopolar manner. In another embodiment, the electrodes may include a first electrode and a second electrode charged with a polarity different from that of the first electrode. For example, the first electrode may have a (+) polarity, and the second electrode may have a (−) polarity. In an alternative embodiment, the first electrode may have a (−) polarity, and the second electrode may have a (+) polarity. In such embodiments, the target substrate SUB and the electrodes may be charged in a bipolar manner.

The coupling bolt CB may couple the first plate PLT1 and the second plate PLT2 to each other. In an embodiment, the coupling bolt CB may be inserted into (or through) the first hole H1 in the first plate PLT1 and into the groove GRV (e.g., into the corresponding groove GRV) in the second plate PLT2. A portion of the coupling bolt CB may be exposed to the outside of the first plate PLT1 through the first hole H1 in the first plate PLT1 and inserted into the groove GRV in the second plate PLT2. Accordingly, the first plate PLT1 and the second plate PLT2 may be coupled to each other.

The height adjusting member HAM may separate the second plate PLT2 from the first plate PLT1. The height adjusting member HAM may contact the second plate PLT2. Accordingly, a height of the second plate PLT2 may be partially adjusted (e.g., minutely adjusted) by using the height adjusting member HAM. For example, a gap between the first plate PLT1 and the second plate PLT2 may be partially adjusted by using the height adjusting member HAM. The height adjusting member HAM may be spaced apart from the coupling bolt CB in a plan view.

In an embodiment, the height adjusting member HAM may include a height adjusting bolt HAB and a washer WS.

The height adjustment bolt HAB may be inserted into the second hole H2 in the first plate PLT1. A portion of the height adjustment bolt HAB may be exposed to the outside of the first plate PLT1 through the second hole H2 in the first plate PLT1 and may contact the second plate PLT2. Accordingly, the second plate PLT2 may be spaced apart from the first plate PLT1. For example, the second plate PLT2 may not contact the first plate PLT1.

The washer WS may have a hole (or opening) passing through its center. The washer WS may be fastened to the height adjusting bolt HAB. For example, the washer WS may be fastened to a lower portion of the height adjusting bolt HAB. The washer WS may more firmly insert (or retain) the height adjustment bolt HAB into the second hole H2.

The height of the second plate PLT2 may vary according to a length of the height adjusting bolt HAB in the second direction D2 and/or a thickness of the washer WS in the second direction D2. For example, a distance between the first plate PLT1 and the second plate PLT2 may vary according to the length of the height adjustment bolt HAB in the second direction D2 and/or the thickness of the washer WS in the second direction D2.

For example, when the height adjustment bolt HAB has a second length longer than a first length, a height of a contact line at where the height adjustment bolt HAB contacts the second plate PLT2 may be increased compared to an embodiment in which the height adjustment bolt HAB has the first length. For example, the length of the height adjustment bolt HAB exposed to the outside of the first plate PLT1 may increase. Accordingly, the height of the second plate PLT2 over the first plate PLT1 may increase. In other words, the distance between the first plate PLT1 and the second plate PLT2 may increase.

When the height adjustment bolt HAB has a third length shorter than the first length, the height of the contact line at where the height adjustment bolt HAB contacts the second plate PLT2 may be decreased compared to an embodiment in which the height adjustment bolt HAB has the first length. For example, the length of the height adjustment bolt HAB exposed to the outside of the first plate PLT1 may decrease. Accordingly, the height of the second plate PLT2 may be decreased. In other words, the distance between the first plate PLT1 and the second plate PLT2 may decrease.

In addition, when the washer WS has a second thickness smaller than a first thickness, the height of the contact line at where the height adjustment bolt HAB contacts the second plate PLT2 may be increased compared to an embodiment in which the washer WS has the first thickness. For example, the length of the height adjustment bolt HAB exposed to the outside of the first plate PLT1 may increase. Accordingly, the height of the second plate PLT2 may be increased. In other words, the distance between the first plate PLT1 and the second plate PLT2 may increase.

When the washer WS has a third thickness smaller than a first thickness, the height of the contact line at where the height adjustment bolt HAB contacts the second plate PLT2 may be decreased compared to an embodiment in which the washer WS has the first thickness. For example, the length of the height adjustment bolt HAB exposed to the outside of the first plate PLT1 may decrease. Accordingly, the height of the second plate PLT2 may be decreased. In other words, the distance between the first plate PLT1 and the second plate PLT2 may decrease.

Accordingly, the height of the second plate PLT2 may be partially adjusted for each position corresponding to the height adjusting member HAM by using (e.g., by adjusting or changing) the height adjusting member HAM. In other words, the distance between the second plate PLT2 and the first plate PLT1 may be partially adjusted through the height adjusting member HAM.

In an embodiment, the length of the height adjustment bolt HAB exposed to the outside of the first plate PLT1 may be shorter than the length of the coupling bolt CB exposed to the outside of the first plate PLT1. Accordingly, the height adjustment bolt HAB may remain coupled between the first plate PLT1 and the second plate PLT2 through the coupling bolt CB and may separate the second plate PLT2 from the first plate PLT1.

In an embodiment, the first plate PLT1 may have a protrusion DP. The protrusion DP may be a portion protruding from the first surface S1 of the first plate PLT1 toward the second plate PLT2. The protrusion DP may be spaced apart from the first hole H1 and the second hole H2 in a plan view. In the embodiment shown in FIG. 3, the first plate PLT1 has two protrusions DP, but the present disclosure is not necessarily limited thereto. In other embodiments, the first plate PLT1 may have one protrusion DP or three or more protrusions DP.

When the first plate PLT1 has the protrusion DP, the second plate PLT2 may only partially contact the first plate PLT1 before being separated from the first plate PLT1 by the height adjusting member HAM. For example, a portion of the second plate PLT2 corresponding to (e.g., aligned with) the protrusion DP may directly contact the first plate PLT1, and a portion of the second plate PLT2 not corresponding to (e.g., offset from) the protrusion DP may not contact the plate PLT1. Accordingly, damage due to contact between the first plate PLT1 and the second plate PLT2 may be reduced or prevented.

According to embodiments, the electrostatic chuck unit EU may have a multi-stage structure including the first plate PLT1 and the second plate PLT2 disposed on the first plate PLT1. Also, the electrostatic chuck unit EU may include the height adjusting member HAM that partially adjusts the height of the second plate PLT2. Thus, the distance between the second plate PLT2 and the first plate PLT1 may be partially adjusted for each position corresponding to the height adjusting member HAM by using the height adjusting member HAM. Accordingly, a flatness of the target substrate SUB seated on the second plate PLT2 can be easily corrected. Accordingly, a gap between the target substrate SUB and the mask sheet MS facing the target substrate SUB can be easily corrected by using the height adjusting member HAM. Accordingly, defects occurring in the deposition process may be reduced or prevented.

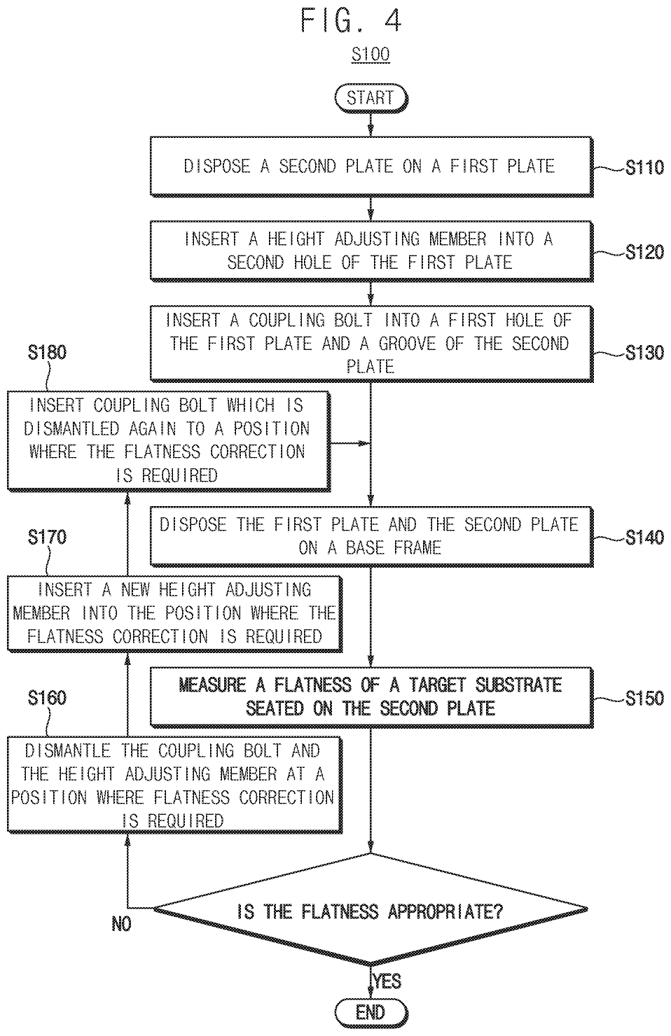

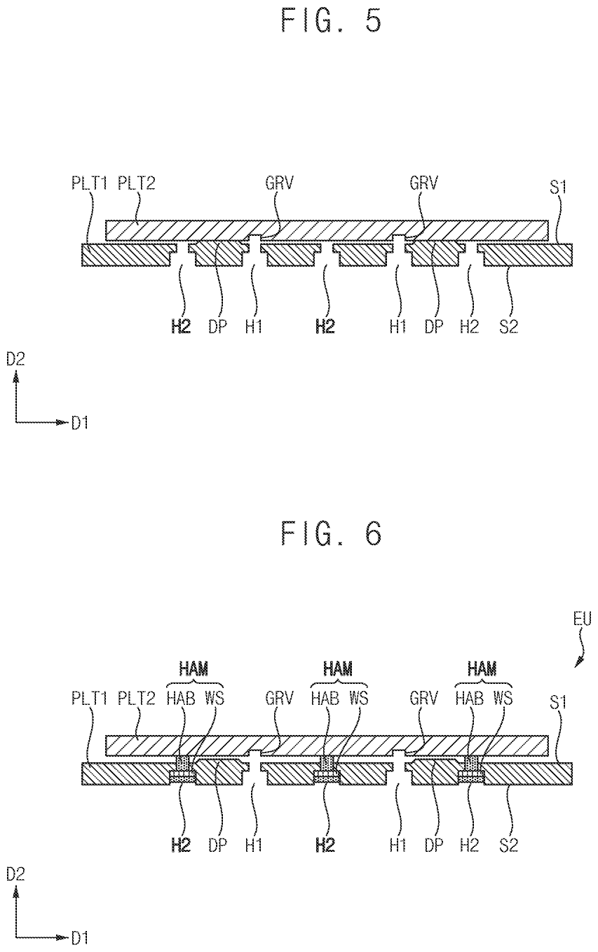

FIG. 4 is a flowchart illustrating steps for adjusting the height of the second plate included in the electrostatic chuck unit shown in FIG. 3, and FIGS. 5 to 10 are cross-sectional views illustrating steps of a method of adjusting the height of the second plate included in the electrostatic chuck unit shown in FIG. 3. Hereinafter, a method of correcting flatness between the target substrate (SUB, see, e.g., FIG. 1) seated on the second plate PLT2 and mask sheets (MS, see, e.g., FIG. 1) facing the target substrate SUB by adjusting the height of the second plate PLT2 will be described in more detail by referring to FIGS. 4 to 10. In the description of FIGS. 4 to 10, reference numerals that are described above identify the same or substantially similar components as described above, and redundant descriptions of such components may be omitted.

As shown in FIG. 5, the second plate PLT2 may be disposed on the first plate PLT1 (S110). Because the first plate PLT1 has the protrusion DP, a portion of the second plate PLT2 corresponding to the protrusion DP may directly contact the first plate PLT1, and a portion of the second plate PLT2 not corresponding to the protrusion DP may not contact the plate PLT1.

As described above, the first plate PLT1 has the first hole H1 and the second hole H2, and the second plate PLT2 has the groove GRV corresponding to the first hole H1 and spaced apart from the second hole H2 in a plan view.

Then, as shown in FIG. 6, the height adjusting member HAM may be inserted into the second hole H2 in the first plate PLT1 (S120). A portion of the height adjustment bolt HAB may be exposed to the outside of the first plate PLT1 through the second hole H2 and may contact the second plate PLT2. Accordingly, the entire second plate PLT2 may be spaced apart from the first plate PLT1. In other words, the entirety of the second plate PLT2 may not contact the first plate PLT1 even at the protrusion DP.

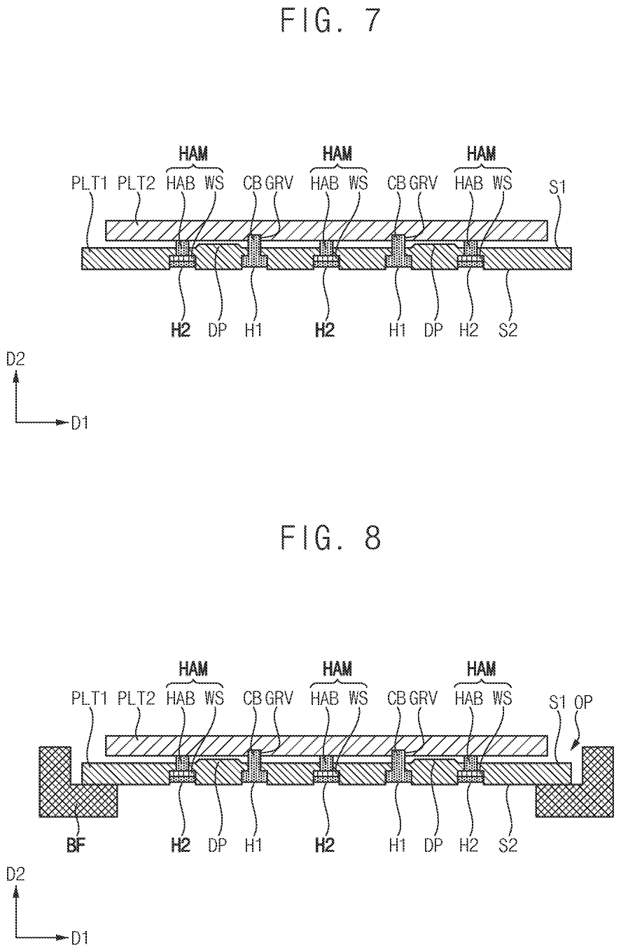

Then, as shown in FIG. 7, the coupling bolt CB may be inserted into the first hole H1 in the first plate PLT1 and into the groove GRV in the second plate PLT2 (S130). A portion of the coupling bolt CB may be exposed to the outside of the first plate PLT1 through the first hole H1 and may be inserted into the groove GRV in the second plate PLT2. Accordingly, the first plate PLT1 and the second plate PLT2 may be coupled together.

Then, as shown in FIG. 8, the first plate PLT1 and the second plate PLT2 may be disposed on the base frame BF (S140). For example, the first plate PLT1 and the second plate PLT2, which are coupled together, are disposed on the base frame BF, and then, the electrostatic chuck unit EU may be disposed in the chamber VC. After the electrostatic chuck unit EU is disposed in the chamber VC, the flatness of the target substrate SUB seated on the second plate PLT2 is measured (S150).

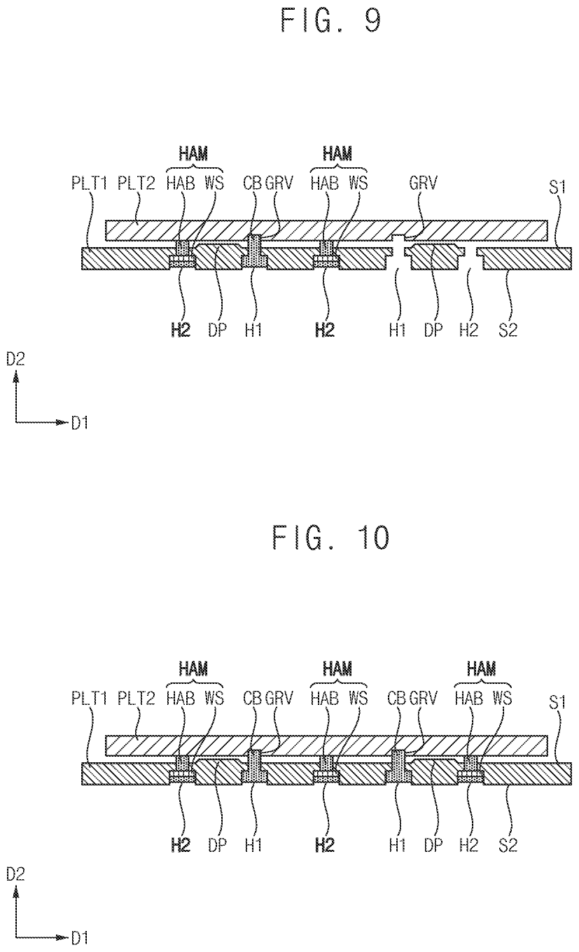

As a result of the flatness measurement, if flatness correction is necessary, the coupling bolt CB and the height adjusting member HAM at a position where the flatness correction is required are dismantled (S160). For example, as shown in FIG. 9, when a height of a right portion of the second plate PLT2 (e.g., a gap between the first plate PLT1 and the second plate PLT2 at the right portion) needs to be adjusted to correct the flatness of the target substrate SUB, the coupling bolt CB and the height adjusting member HAM located on the right portion may be dismantled (or removed). For example, the coupling bolt CB may be dismantled from the first hole H1 and the groove GRV, and the height adjusting member HAM may be dismantled from the second hole H2.

After that, as shown in FIG. 10, a new height adjusting member HAM is inserted into the position where the flatness correction is required (S170). Accordingly, the height of the second plate PLT2 may be adjusted.

The new height adjusting member HAM may include a height adjusting bolt HAB having a length in the second direction D2 that is different from the original (or prior) height adjusting member HAM and/or the washer WS whose thickness in the second direction D2 is different from the original (or prior) washer WS.

For example, when the height adjusting member HAM having the height adjusting bolt HAB having the second length that is longer than the first length is inserted in the second hole H2 at where the height adjusting member HAM having the height adjusting bolt HAB having the first length was removed, the height of the contact line at which the height adjustment bolt HAB contacts the second plate PLT2 may be increased. Accordingly, the height of the second plate PLT2 may increase at a position at where the flatness correction is necessary. In other words, the distance between the first plate PLT1 and the second plate PLT2 may increase at a position where the flatness correction is required.

When the height adjusting member HAM having the height adjusting bolt HAB having the third length that is shorter than the first length is inserted in the second hole H2 at where the height adjusting member HAM having the height adjusting bolt HAB having the first length was removed, the height of the contact line at which the height adjustment bolt HAB contacts the second plate PLT2 may be decreased. Accordingly, the height of the second plate PLT2 may decrease at a position at where the flatness correction is required. In other words, the distance between the first plate PLT1 and the second plate PLT2 may decrease at a position at where the flatness correction is required.

In addition, when the height adjusting member HAM having the washer WS having the second thickness larger than the first thickness is inserted in the second hole H2 at where the height adjusting member HAM having the washer WS having the first thickness was removed, the height of the contact line at which the height adjustment bolt HAB contacts the second plate PLT2 may be increased. Accordingly, the height of the second plate PLT2 may increase at a position where the flatness correction is required. In other words, the distance between the first plate PLT1 and the second plate PLT2 may increase at a position where the flatness correction is required.

When the height adjusting member HAM having the washer WS having the third thickness that is smaller than the first thickness is inserted in the second hole H2 at where the height adjusting member HAM having the washer WS having the first thickness was removed, the height of the contact line at which the height adjustment bolt HAB contacts the second plate PLT2 may be decreased. Accordingly, the height of the second plate PLT2 may decrease at a position where the flatness correction is required. In other words, the distance between the first plate PLT1 and the second plate PLT2 may decrease at a position where the flatness correction is required.

Thereafter, the coupling bolt CB, which was dismantled, may be inserted again (e.g., reinserted) to a position where the flatness correction is required (S180). Accordingly, in a state in which the height of the second plate PLT2 is adjusted, the first plate PLT1 and the second plate PLT2 may be coupled (or fully coupled) again. Thereafter, the first plate PLT1 and the second plate PLT2 may be disposed on the base frame BF (S140), and the flatness of the target substrate SUB seated on the second plate PLT2 may be measured (S150). Steps S140, S150, S160, S170 and S180 may be repeatedly performed until the measured flatness satisfies a desired value.

As a result of the flatness measurement, when the flatness satisfies the desired value and flatness correction is not required, the operation proceeds without an additional flatness correction step.

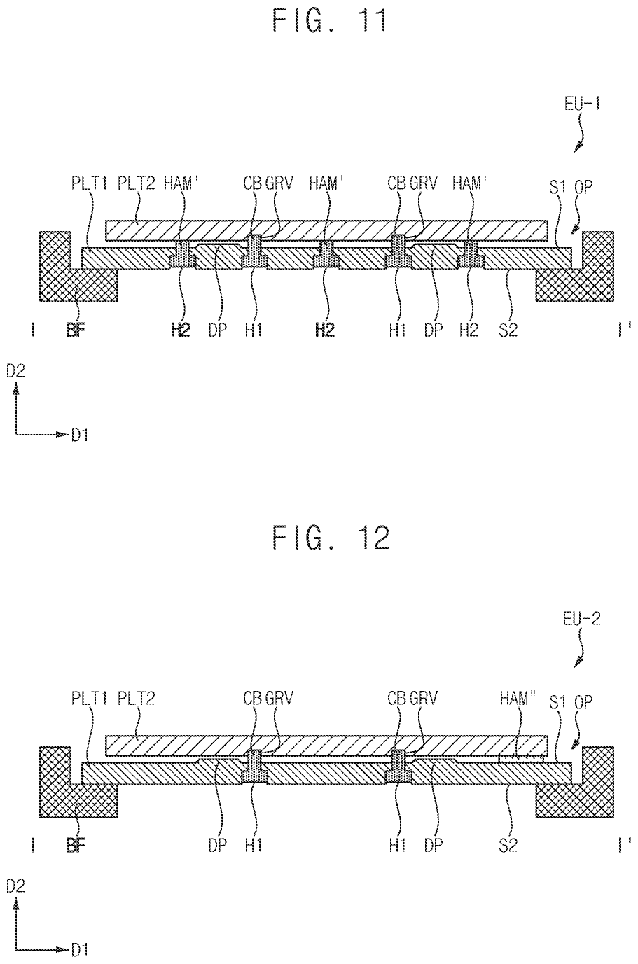

FIG. 11 is a cross-sectional view illustrating an electrostatic chuck unit according to another embodiment. For example, FIG. 11 may correspond to the cross-sectional view of FIG. 3.

Referring to FIG. 11, an electrostatic chuck unit EU-1 according to another embodiment may be substantially same as the electrostatic chuck unit EU described with reference to FIGS. 1 to 3 except for a height adjusting member HAM′. Therefore, redundant descriptions will be omitted.

In the embodiment shown in FIG. 11, the washer WS is omitted. In such an embodiment, the height adjusting member HAM′ may refer to the height adjusting bolt (HAB, see, e.g., FIG. 3) itself. In such an embodiment, the height of the contact line at where the height adjustment bolt HAB contacts the second plate PLT2 may vary according to the length of the height adjustment bolt HAB in the second direction D2.

FIG. 12 is a cross-sectional view illustrating an electrostatic chuck unit according to another embodiment. For example, FIG. 12 may correspond to the cross-sectional view of FIG. 3.

Referring to FIG. 12, an electrostatic chuck unit EU-2 according to another embodiment may be substantially same as the electrostatic chuck unit EU described with reference to FIGS. 1 to 3 except for a height adjusting member HAM″. Therefore, redundant descriptions will be omitted.

In the embodiment shown in FIG. 12, the height adjusting member HAM″ is a spacer disposed between the first plate PLT1 and the second plate PLT2. The spacer HAM″-=may be formed of a metal material, an inorganic insulating material, ceramic, or the like. Examples of metal materials that can be used as the spacer HAM″ may include aluminum (Al), platinum (Pt), palladium (Pd), silver (Ag), magnesium (Mg), gold (Au), nickel (Ni), neodymium (Nd)), iridium (Ir), chromium (Cr), lithium (Li), calcium (Ca), molybdenum (Mo), titanium (Ti), tungsten (W), copper (Cu), or the like. These materials may be used alone or in combination with each other. In addition, examples of inorganic insulating materials that can be used as the spacer HAM″ may include silicon oxide (SiO₂), silicon nitride (SiNₓ), silicon oxynitride (SiON), aluminum oxide (Al₂O₃), titanium oxide (TiO₂), and tantalum oxide (Ta₂O₅), hafnium oxide (HfO₂), zinc oxide (ZnO₂), or the like. These materials may be used alone or in combination with each other. In an embodiment, the spacer HAM″ may be formed of the same material as the first plate PLT1 and/or the second plate PLT2.

The height of the second plate PLT2 may vary according to a thickness of the height adjusting member (or the spacer) HAM″ in the second direction D2. In other words, the distance between the first plate PLT1 and the second plate PLT2 may vary according to the thickness of the height adjusting member HAM″ in the second direction D2.

For example, when the height adjusting member HAM″ has a second thickness larger than a first thickness, a height of a contact line at which the height adjusting member (or the spacer) HAM″ contacts the second plate PLT2 may be increased compared to an embodiment in which the height adjusting member (or the spacer) HAM″ has the first thickness. Accordingly, the height of the second plate PLT2 may be increased. In other words, the distance between the first plate PLT1 and the second plate PLT2 may increase.

When the height adjusting member HAM″ has a third thickness smaller than a first thickness, a height of a contact line at which the height adjusting member (or the spacer) HAM″ contacts the second plate PLT2 may be decreased compared to a case where the height adjusting member HAM″ has the first thickness. Accordingly, the height of the second plate PLT2 may be decreased. In other words, the distance between the first plate PLT1 and the second plate PLT2 may decrease.

Accordingly, the height of the second plate PLT2 may be partially adjusted for each position corresponding to the height adjusting member HAM″ by changing the height adjusting member HAM″. In other words, the distance between the second plate PLT2 and the first plate PLT1 may be partially adjusted through the height adjusting member HAM″.

When the height adjusting member HAM″ is a spacer disposed between the first plate PLT1 and the second plate PLT2, the first plate PLT1 may not have the second hole H2 described with reference to FIG. 3.

According to embodiments, the electrostatic chuck unit may have a multi-stage structure including the first plate PLT1 and the second plate PLT2 disposed on the first plate PLT1. Also, the electrostatic chuck unit EU may include the height adjusting member that partially adjusts the height of the second plate PLT2. For example, the distance between the second plate PLT2 and the first plate PLT1 may be partially adjusted for each position corresponding to the height adjusting member through (e.g., by using or selecting) the height adjusting member. Accordingly, the flatness of the target substrate SUB seated on the second plate PLT2 can be easily adjusted and corrected. Accordingly, the distance between the target substrate SUB and the mask sheet MS facing the target substrate SUB can be easily corrected through the height adjusting member. Accordingly, defects occurring in the deposition process may be reduced or prevented.

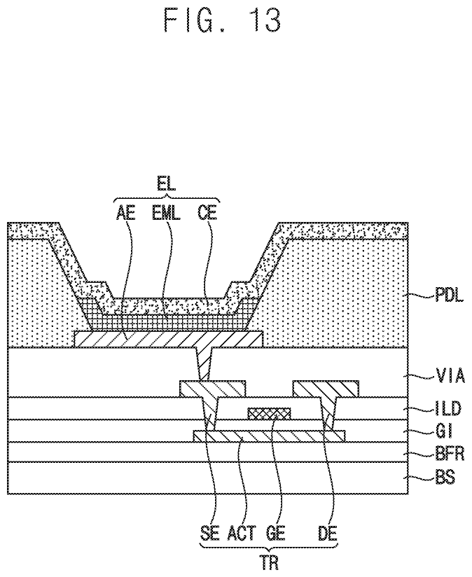

FIG. 13 is a cross-sectional view illustrating a pixel formed during a deposition process by using the deposition apparatus shown in FIG. 1.

Referring to FIG. 13, a pixel PX may include a base substrate BS, a buffer layer BFR, a transistor TR, a gate insulating layer GI, an interlayer insulating layer ILD, a via insulating layer VIA, a light emitting device EL, and a pixel defining layer PDL. The transistor TR may include an active layer ACT, a gate electrode GE, a source electrode SE, and a drain electrode DE. The light emitting device EL may include a first electrode AE, an emission layer EML, and a second electrode CE.

The base substrate BS may include glass, quartz, plastic, or the like. In an embodiment, the base substrate BS may have flexible, bendable, or rollable characteristics.

The buffer layer BFR may be disposed on the base substrate BS. The buffer layer BFR may include an inorganic insulating material. For example, the buffer layer BFR may include silicon oxide, silicon nitride, silicon oxynitride, or the like. The buffer layer BFR may block impurities so that the active layer ACT of the transistor TR is not damaged by impurities diffused through the base substrate BS.

The active layer ACT may be disposed on the buffer layer BFR. In an embodiment, the active layer ACT may include a silicon semiconductor material. For example, the active layer ACT may include amorphous silicon or polycrystalline silicon. In another embodiment, the active layer ACT may include an oxide semiconductor material. For example, the active layer ACT may include zinc oxide, zinc-tin oxide, zinc-indium oxide, indium oxide, titanium oxide, indium-gallium-zinc oxide, indium-zinc-tin oxide, or the like.

The gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, tantalum oxide, or the like. The gate insulating layer GI may electrically insulate the active layer ACT and the gate electrode GE from each other.

The gate electrode GE may be disposed on the gate insulating layer GI. The gate electrode GE may include a conductive material. For example, the gate electrode GE may include a metal, an alloy, a conductive metal oxide, a transparent conductive material, or the like. A gate signal may be applied to the gate electrode GE. The gate signal may turn on/off the transistor TR to adjust electrical conductivity of the active layer ACT.

The interlayer insulating layer ILD may be disposed on the gate electrode GE. The interlayer insulating layer ILD may include an organic insulating material and/or an inorganic insulating material. The interlayer insulating layer ILD may electrically insulate the source electrode SE and drain electrode DE from the gate electrode GE.

The source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, a transparent conductive material, or the like. Each of the source electrode SE and the drain electrode DE may electrically contact the active layer ACT through a contact hole (or contact opening) passing through the interlayer insulating layer ILD and the gate insulating layer GI.

The via insulating layer VIA may be disposed on the source electrode SE and the drain electrode DE. The via insulating layer VIA may include an organic insulating material. For example, the via insulating layer VIA may include a polyacrylic resin, a polyimide resin, an acrylic resin, or the like. Accordingly, an upper surface of the via insulating layer VIA may be substantially flat.

The first electrode AE may be disposed on the via insulation layer VIA. The first electrode AE may include a conductive material. For example, the first electrode AE may include a metal, an alloy, a conductive metal oxide, a transparent conductive material, or the like. The first electrode AE may electrically contact the source electrode SE or the drain electrode DE through a contact hole (or contact opening) penetrating the via insulating layer VIA.

The pixel defining layer PDL may be disposed on the first electrode AE. The pixel defining layer PDL may include an organic insulating material. For example, the pixel defining layer PDL may include a polyacryl-based compound or a polyimide-based compound. The pixel defining layer PDL may partition an emission area of each of the plurality of pixels. The pixel defining layer PDL may define a pixel opening exposing the first electrode AE.

The emission layer EML may be disposed on the first electrode AE in the pixel opening. The emission layer EML may include an organic light emitting material. In an embodiment, the emission layer EML may have a multilayer structure including various functional layers. For example, the emission layer EML may further include at least one of a hole injection layer, a hole transport layer, an electron transport layer, and an electron injection layer.

The second electrode CE may be disposed on the emission layer EML and may cover the pixel defining layer PDL.

In an embodiment, the emission layer EML may be formed by depositing deposition materials on the first electrode AE. In other words, the emission layer EML may be formed by a deposition process using a deposition apparatus (e.g., the deposition apparatus 1000 shown in FIG. 1).

However, the present disclosure is not limited thereto, and a layer formed through the deposition process may be one or more functional layers, such as a hole transport layer and an electron transport layer, or may be a capping layer or an encapsulation layer disposed on the second electrode CE.

The present disclosure should not be construed as being limited to the embodiments set forth herein. Rather, these embodiments are provided so that this disclosure will be thorough and complete and will fully convey the aspects and features of the present disclosure to those skilled in the art.

While the present disclosure has been particularly shown and described with reference to embodiments thereof, it will be understood by those of ordinary skill in the art that various changes in form and details may be made therein without departing from the spirit or scope of the present disclosure as defined by the following claims and their equivalents.

What is claimed is:

1. An electrostatic chuck unit comprising:
a first plate having a first surface and a second surface facing each other and a first hole extending from the first surface to the second surface;
a second plate on the first surface of the first plate and having a groove corresponding to the first hole;
a coupling bolt inserted into the first hole and the groove; and
a height adjusting member spaced apart from the coupling bolt in a plan view.

2. The electrostatic chuck unit of claim 1, wherein the first plate has a second hole extending from the first surface to the second surface and spaced apart from the groove in the plan view, and
wherein the height adjusting member comprises a height adjusting bolt inserted into the second hole.

3. The electrostatic chuck unit of claim 2, wherein a length of the height adjusting bolt exposed through the first plate is shorter than a length of the coupling bolt exposed through the first plate.

4. The electrostatic chuck unit of claim 2, wherein the height adjusting member further comprises a washer on the height adjusting bolt.

5. The electrostatic chuck unit of claim 1, wherein the height adjusting member is a spacer between the first plate and the second plate.

6. The electrostatic chuck unit of claim 5, wherein the spacer comprises at least one selected from a metal material, an inorganic insulating material, and ceramic.

7. The electrostatic chuck unit of claim 6, wherein the spacer comprises a same material as the first plate and the second plate.

8. The electrostatic chuck unit of claim 1, wherein the height adjusting member contacts the second plate.

9. The electrostatic chuck unit of claim 1, wherein the second plate is spaced apart from the first plate by the height adjusting member.

10. The electrostatic chuck unit of claim 1, wherein the first plate and the second plate are coupled to each other by the coupling bolt.

11. The electrostatic chuck unit of claim 1, wherein the first plate has a protrusion protruding from the first surface toward the second plate.

12. The electrostatic chuck unit of claim 1, wherein the first plate and the second plate comprise at least one selected from a metal material, an inorganic insulating material, and ceramic.

13. The electrostatic chuck unit of claim 12, wherein the first plate and the second plate comprise the same material as each other.

14. The electrostatic chuck unit of claim 1, further comprising a base frame supporting the first plate and the second plate.

15. The electrostatic chuck unit of claim 14, wherein the base frame has an opening, and
wherein the first plate and the second plate are in the opening.

16. A deposition apparatus comprising:
a chamber;
a mask unit in the chamber and comprising a mask sheet and a mask frame supporting the mask sheet; and
an electrostatic chuck unit in the chamber and configured to receive a target substrate thereon, the electrostatic chuck unit comprising:
a first plate having a first surface and a second surface facing each other and a first hole extending from the first surface to the second surface;
a second plate on the first surface of the first plate and having a groove corresponding to the first hole;
a coupling bolt inserted into the first hole and the groove; and
a height adjusting member spaced apart from the coupling bolt in a plan view.

17. The deposition apparatus of claim 16, wherein the first plate has a second hole extending from the first surface to the second surface and spaced apart from the groove in the plan view, and
wherein the height adjusting member comprises a height adjusting bolt inserted into the second hole.

18. The deposition apparatus of claim 16, wherein the height adjusting member is a spacer between the first plate and the second plate.

19. The deposition apparatus of claim 16, wherein the second plate is spaced apart from the first plate by the height adjusting member.

20. The deposition apparatus of claim 16, wherein the electrostatic chuck unit and the mask unit are arranged such that the target substrate and the mask sheet face each other along a direction parallel to the ground.
